(19) United States
(12) Patent Application Publication
(10) Pub. No.: US 2025/0120130 A1
(43) Pub. Date: Apr. 10, 2025

(54) SEMICONDUCTOR DEVICE INCLUDING TWO-DIMENSIONAL MATERIAL AND METHOD OF FABRICATING THE SEMICONDUCTOR DEVICE

(71) Applicant: Samsung Electronics Co., Ltd., Suwon-si (KR)

(72) Inventors: Minsu SEOL, Suwon-si (KR); Changhyun KIM, Suwon-si (KR); Kyung-Eun BYUN, Suwon-si (KR); Eunkyu LEE, Suwon-si (KR)

(73) Assignee: Samsung Electronics Co., Ltd., Suwon-si (KR)

(21) Appl. No.: 18/823,988

(22) Filed: Sep. 4, 2024

(30) Foreign Application Priority Data
Oct. 4, 2023 (KR) 10-2023-0131937

(51) Int. Cl. H01L 29/76; H01L 21/02; H01L 29/24; H01L 29/423; H01L 29/66; H01L 29/786

(52) U.S. Cl. CPC H10D 48/362; H01L 21/02568; H01L 21/0262; H10D 30/6735; H10D 30/6757; H10D 62/80; H10D 99/00

(57) ABSTRACT

Provided are a semiconductor device and a method of manufacturing the semiconductor device. The semiconductor device includes a source electrode provided on a substrate, a drain electrode disposed away from the source electrode, and a channel connected between the source electrode and the drain electrode, wherein the channel includes a plurality of first channel layers and plurality of second channel layers, and the gate electrode is provided on one surface and another surface of each of the plurality of the first channel layers and on one surface and another surface of each of the plurality of the second channel layers.

### CROSS-REFERENCE TO RELATED APPLICATION

This application is based on and claims priority under 35 U.S.C. § 119 to Korean Patent Application No. 10-2023-0131937, filed on Oct. 4, 2023 in the Korean Intellectual Property Office, the disclosure of which is incorporated by reference herein in its entirety.

### BACKGROUND

### 1. Field

The disclosure relates to a semiconductor device including a two-dimensional material and a method of manufacturing the same.

### 2. Description of the Related Art

A transistor is a semiconductor device with an electrical switching function and may be employed in various integrated circuit devices including a memory devices, drive integrated circuits (ICs), and a logic devices. In order to increase the degree of integration of integrated circuit devices, the space occupied by transistors provided therein has been rapidly decreased, and research has been conducted to maintain the performance of integrated circuits while reducing the size of transistors.

One element of a transistor is a gate electrode. When a voltage is applied to the gate electrode, a channel adjacent to the gate may open a path for current, and in the opposite case it may block the path for current. The performance of a semiconductor may depend on how much leakage current is reduced and how well the leakage current is managed at the gate electrode and channel. As the area becomes larger where the channel and gate electrode that control the current in the transistor contact, the power efficiency of the transistor may become higher.

As semiconductor processes are becoming more refined, the size of transistors has been decreased along with the area where the gate electrode and the channel contact each other, which may cause a short channel effect. For example, phenomena such as threshold voltage variation, carrier velocity saturation, and degradation of the subthreshold characteristics may occur. Accordingly, measures to effectively reduce these effects have been sought.

### SUMMARY

Provided is a semiconductor device having a structure in which a gate electrode surrounds an entire surface of a channel.

Provided is a method of manufacturing a semiconductor device having a structure in which a gate electrode surrounds an entire surface of a channel.

Additional aspects will be set forth in part in the description which follows and, in part, will be apparent from the description, or may be learned by practice of the presented embodiments of the disclosure.

According to an embodiment of the disclosure, a semiconductor device may include a substrate; a source electrode and a drain electrode spaced apart from each other on the substrate; a channel between the source electrode and the drain electrode, the channel including a two-dimensional material; and a gate electrode between the source electrode and the drain electrode. The channel may include a plurality of first channel layers and a plurality of second channel layers. The plurality of the first channel layers may be parallel to each other and spaced apart from each other. The plurality of the second channel layers may be perpendicular to the plurality of the first channel layers and between the plurality of the first channel layers. The plurality of second channel layers, respectively, may be alternately provided at a first end of each of the plurality of the first channel layers and a second end of each of the plurality of the first channel layers. The gate electrode may be on a first surface of each of the plurality of first channel layers and a second surface of each of the plurality of first channel layers. The gate electrode may be on a first surface of each of the plurality of second channel layers and a second surface of each of the plurality of second channel layers.

In some embodiments, a gate insulation material may be between the channel and the gate electrode.

In some embodiments, a spacer may be between the channel and the gate insulation material.

In some embodiments, the plurality of the first channel layers may be parallel to a top surface of the substrate.

In some embodiments, the plurality of the first channel layers may be perpendicular to a top surface of the substrate.

In some embodiments, the channel may further include a plurality of third channel layers spaced apart from the plurality of the first channel layers, a plurality of fourth channel layers between the plurality of the third channel layers in a direction perpendicular to the plurality of the third channel layers, and a central channel layer above the plurality of the first channel layers and the plurality of the third channel layers. The plurality of fourth channel layers, respectively, may be alternately provided at a first end of each of the plurality of third channel layers and a second end of each of the plurality of third channel layers. The plurality of second channel layers and the plurality of fourth channel layers may be provided symmetrically with respect to a center of the central channel layer.

In some embodiments, the plurality of the first channel layers may be perpendicular to a top surface of the substrate.

In some embodiments, the two-dimensional material may have a bandgap of 0.1 eV or more.

In some embodiments, the two-dimensional material may include MoS₂, MoSe₂, MoTe₂, WS₂, or black phosphorus, or a combination thereof.

In some embodiments, in a cross-sectional cut across between the source electrode and the drain electrode, a length of the first channel layer may be between 10 nm and 500 nm.

In some embodiments, in a cross-sectional cut across between the source electrode and the drain electrode, a length of the second channel layer may be between 5 nm and 50 nm.

According to an embodiment of the disclosure, a method of manufacturing a semiconductor device may include stacking a first sacrificial layer and a second sacrificial layer on a substrate; removing the second sacrificial layer; forming a channel including a two-dimensional material on the first sacrificial layer; removing the first sacrificial layer; and forming a gate electrode between a source electrode and a drain electrode on the substrate. The forming the channel may include forming a plurality of first channel layers and a plurality of second channel layers. The plurality of the first channel layers may be parallel to each other and spaced apart from each other. The plurality of the second channel layers may be perpendicular to the plurality of the first channel layers and between the plurality of the first channel layers. The plurality of second channel layers, respectively, may be alternatively provided at a first end of each of the plurality of the first channel layers and a second end of each of the plurality of the first channel layers. The forming the gate electrode may include forming the gate electrode on a first surface of each of the plurality of the first channel layers, a second surface of each of the plurality of the first channel layers, a first surface of each of the plurality of the second channel layers, and a second surface of each of the plurality of the second channel layers.

In some embodiments, the method may further include forming a gate insulation material on the channel before the forming the gate electrode. The forming the gate electrode may include forming the gate electrode on the gate insulation material so the gate insulation material may be between the channel and the gate electrode.

In some embodiments, the plurality of the first channel layers may be parallel to a top surface of the substrate.

In some embodiments, the plurality of the first channel layers may be perpendicular to a top surface of the substrate.

In some embodiments, the two-dimensional material may have a bandgap of 0.1 eV or more.

In some embodiments, the two-dimensional material may include MoS₂, MoSe₂, MoTe₂, WS₂, or black phosphorus, or a combination thereof.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a perspective view of a semiconductor device including a 2D material according to an embodiment;

FIG. 2 is a perspective view illustrating a schematic structure of a channel and a gate electrode of a semiconductor device according to an embodiment;

FIG. 3 is a cross-sectional view taken along a line I-I of the semiconductor device of FIG. 1;

FIGS. 4 to 6 are different cross-sectional views taken along a line II-II of the semiconductor device of FIG. 1;

FIG. 7 is a perspective view illustrating a schematic structure of a channel and a gate electrode of a semiconductor device according to the other embodiment;

FIG. 8 is a cross-sectional view taken along a line I′-I′ of the semiconductor device of FIG. 7;

FIGS. 9 and 11 are different cross-sectional views taken along a line II′-II′ of the semiconductor device of FIG. 7;

FIGS. 10 and 12 are different cross-sectional views taken along a line III′-III′ of the semiconductor device of FIG. 7;

FIG. 13 is a perspective view illustrating a schematic structure of a channel and a gate electrode of a semiconductor device according to another embodiment;

FIG. 14 is a cross-sectional view taken along a line I″-I″ of the semiconductor device of FIG. 13;

FIGS. 15 to 17 are different cross-sectional views taken along a line II″-II″ of the semiconductor device of FIG. 13;

FIGS. 18 to 25 illustrate a method of manufacturing a semiconductor, according to an embodiment;

FIG. 26 is a block diagram illustrating an electronic device according to an embodiment; and

FIGS. 27 to 30 are block diagrams illustrating electronic devices according to embodiments.

### DETAILED DESCRIPTION

Reference will now be made in detail to embodiments, examples of which are illustrated in the accompanying drawings, wherein like reference numerals refer to like elements throughout. In this regard, the embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C,” “at least one of A, B, or C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

Hereinafter, a semiconductor device and a method of manufacturing a semiconductor device according to various embodiments will be described in detail with reference to the accompanying drawings. In the following drawings, the same reference numerals refer to the same components, and the size of each component in the drawings may be exaggerated for clarity and convenience of explanation. The terms, such as “a first,” “a second,” etc., may be used to describe various components, but components should not be limited by terms. Terms are used only for the purpose of distinguishing one component from another.

Singular expressions include plural expressions, unless the context clearly indicates otherwise. Also, when a part “comprises” a component, this means that it may include more other components, rather than excluding other components, unless otherwise stated. Further, the size or thickness of each component in the drawing may be exaggerated for clarity of explanation. In addition, when a certain material layer is explained to exist on a substrate or another layer, the material layer may exist in direct contact with the substrate or another layer, or another third layer may exist in between. Since the materials constituting each layer in the examples below are exemplary, other materials may be used.

In addition, the terms “ . . . part” and “module” described in the specification refer to units that process at least one function or operation, which can be implemented in hardware or software or by combining hardware and software.

The specific executions described in the embodiment are examples and do not limit the technical scope in any way. For the sake of simplicity of the specification, descriptions of conventional electronic configurations, control systems, software, and other functional aspects of the systems may be omitted. Furthermore, the connections or connecting members of the lines between the components shown in the drawing exemplify functional connections and/or physical or circuit connections, and in actual devices, they may be represented as replaceable or additional various functional connections, physical connections, or circuit connections.

The use of the term “said” and similar indicative terms may correspond to both singular and plural.

The operations in a method may be performed in an appropriate order unless there is an explicit mention that the operations should be performed in the order described. In addition, the use of all example terms (e.g., etc.) is simply to explain technical ideas in detail, and the scope of rights is not limited by these terms unless it is limited by the claim.

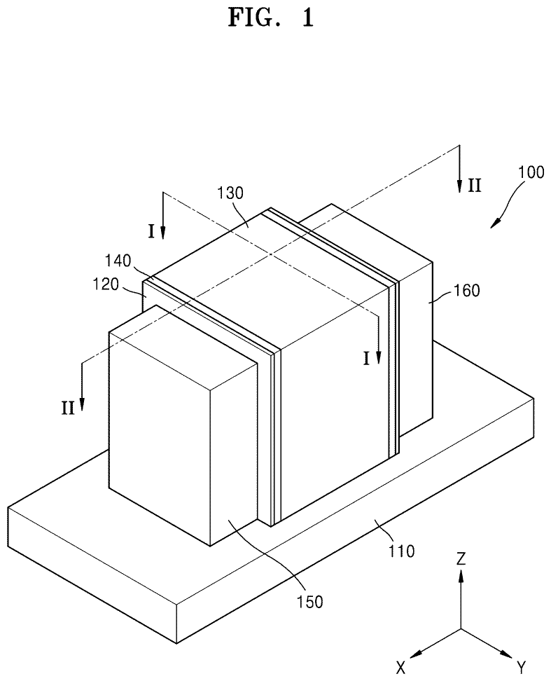

FIG. 1 is a perspective view illustrating a schematic structure of a semiconductor device 100 according to an embodiment.

The semiconductor device 100 may include a substrate 110, a source electrode 150 disposed on the substrate 110, a drain electrode 160 disposed to be spaced apart from the source electrode 150, a channel 120 connected between the source electrode 150 and the drain electrode 160, and a gate electrode 130 insulated from the source electrode 150 and the drain electrode 160. A gate insulating material 140 may be provided between the channel 120 and the gate electrode 130.

The substrate 110 may be an insulated substrate, or a semiconductor substrate having an insulating layer formed on a surface thereof. The semiconductor substrate may include, for example, a Si, Ge, SiGe, or a group III-V semiconductor material. The substrate 110 may be, for example, a silicon substrate having a silicon oxide formed on a surface thereof, but is not limited thereto.

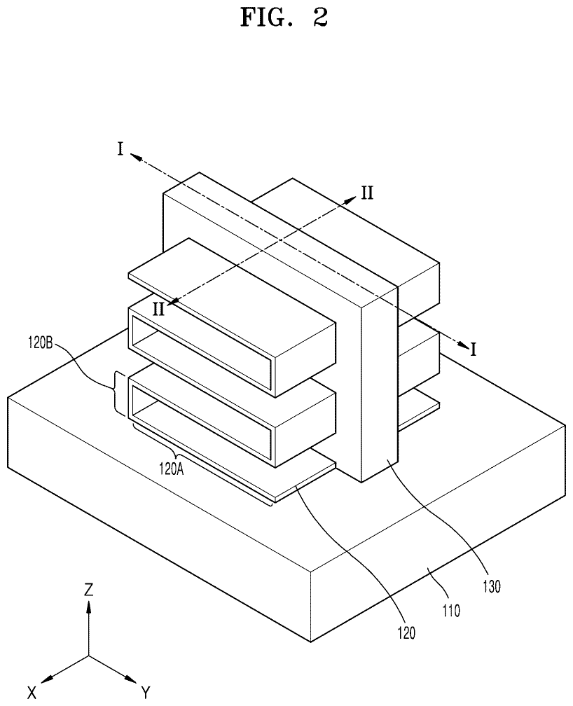

FIG. 2 is a perspective view illustrating a schematic structure of a channel and gate electrode of a semiconductor device according to an embodiment.

Referring to FIG. 2, the channel 120 may be provided on the substrate 110. The channel 120 may have a corrugated structure. The channel 120 may include a plurality of first channel layers 120A and a plurality of second channel layers 120B. The plurality of the first channel layers 120A may be disposed to be spaced apart from each other in a direction (Z direction) perpendicular to the substrate 110. Each of the plurality of the first channel layers 120A may be parallel to one surface (e.g., top surface) of the substrate 110, for example, as shown in FIG. 2. A plurality of second channel layers 120B may be provided between the plurality of the first channel layers 120A. The plurality of the second channel layers 120B may be provided in a direction perpendicular to the plurality of the first channel layers 120A. The plurality of the second channel layers 120B may be alternately provided at one end and the other end of the plurality of the first channel layers 120A. Each second channel layer 120B may connect a first end of one first channel layer 120A to a first end of another first channel layer 120A thereabove or may connect a second end of one first channel layer 120A to a second end of another channel layer 120A thereabove.

The gate electrode 130 may be provided on the channel 120. In FIG. 2, only a part of the gate electrode 130 is illustrated to show the structure of the channel 120, but the gate electrode 130 may be provided to surround the channel 120. That is, the gate electrode 130 may be provided to surround the entire side of the channel 120 including (or consisting of) a plurality of first channel layers 120A and a plurality of second channel layers 120B. The embodiment may have a so-called gate-all-around (GAA) structure. All of one surface and the other surface of the plurality of the first channel layers 120A may be surrounded by the gate electrode 130, and all of the one surface and the other surface of the plurality of the second channel layers 120B may be surrounded by the gate electrode 130. For example, both the Z-axis direction and the opposite direction of the first channel layer 120A may be surrounded by the gate electrode 130, and both the Y-axis direction and the opposite direction of the second channel layer 120B may be surrounded by the gate electrode 130.

Although FIG. 2 illustrates that the first channel layer 120A closest to the substrate 110 among the plurality of the first channel layers 120A is spaced apart from the substrate 110 by a predetermined distance, the first channel layer 120A may be provided to contact the substrate 110. In this case, the gate electrode 130 may be provided only on one of both surfaces of the first channel layer 120A closest to the substrate 110 among the plurality of the first channel layers 120A with the gate insulating material 140 interposed therebetween.

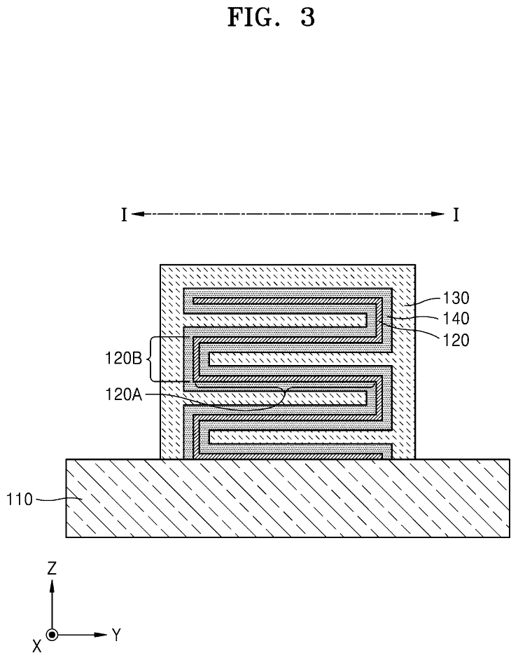

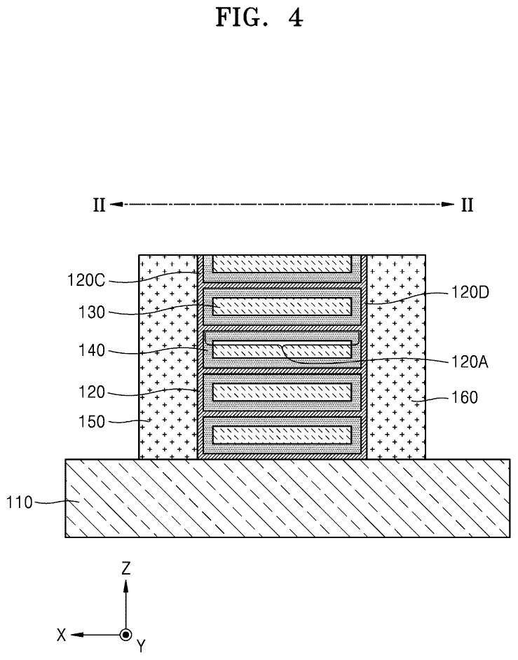

FIG. 3 is a cross-sectional view of the semiconductor device along the line I-I of FIG. 1, and FIGS. 4 to 6 are different cross-sectional views of the semiconductor device along the line II-II of FIG. 1. The cross-section denoted with I-I may represent a first cross-section in which the cross-section denoted with II-II is cut across the source electrode 150 and the drain electrode 160 (Y direction in the drawing) in a direction perpendicular to the substrate 110 (Z direction in the drawing). The cross-section denoted with II-II may represent a second cross-section cut across from the source electrode 150 to the drain electrode 160 (X direction in the drawing) in a direction perpendicular to the substrate 110 (Z direction in the drawing). Here, since the substrate 110 may not be a complete plane, the vertical direction may include not only a substantial vertical direction but also a general vertical direction. In the specification, the above-described definitions for the first cross-section and the second cross-section are to be used in common.

Referring to FIG. 3, as described in FIG. 2, the channel 120 may have a corrugated structure. The channel 120 may include a plurality of first channel layers 120A and a plurality of second channel layers 120B. Each of the plurality of the second channel layers 120B may be provided between the plurality of the first channel layers 120A, and the plurality of the second channel layers 120B may be provided in a direction perpendicular to the plurality of the first channel layers 120A. The plurality of the second channel layers 120B may be alternately provided at one end and the other end of the plurality of the first channel layers 120A. The length of the first channel layer 120A may be longer than the length of the second channel layer 120B. For example, the length of the first channel layer 120A may be approximately between 5 nm or more and 1000 nm or less. Alternatively, the length of the first channel layer 120A may be approximately between 10 nm or more and 500 nm or less. For example, the length of the second channel layer 120B may be approximately between 3 nm or more and 100 nm or less. Alternatively, the length of the second channel layer 120B may be between 5 nm or more and 50 nm or less.

The channel 120 may include two-dimensional material. The two-dimensional material may include graphene, black phosphorus, phosphorene, transition metal dichalcogenide, or a combination thereof. The transition metal dichalcogenide may include one metal element selected from the group including (or consisting of) Mo, W, Nb, V, Ta, Ti, Zr, Hf, Tc, Re, Cu, Ga, In, Sn, Ge, and Pb, and one chalcogen element selected from the group including (or consisting of) S, Se, and Te. For example, the two-dimensional material may include MoS₂, MoSe₂, MoTe₂, WS₂, or a combination thereof. The two-dimensional material may have a bandgap greater than or equal to 0.1 eV.

The gate electrode 130 may surround the entire side of the channel 120, thereby having a GAA structure. Gate insulating material 140 may be provided between the channel 120 and the gate electrode 130. The gate electrode 130 may be provided in the gate insulating material 140. The gate electrode 130 may be provided on both surfaces of the first channel layer 120A and both surfaces of the second channel layer 120B with the gate insulating material 140 interposed therebetween.

Referring to FIG. 4, the channel 120 may be connected between the source electrode 150 and the drain electrode 160 to become a path through which currents flow between the source electrode 150 and the drain electrode 160. The channel 120 may be in direct contact with the source electrode 150 and the drain electrode 160. However, the channel 120 is not limited here, and it is also possible for the channel 120 to be connected to the source electrode 150 and drain electrode 160 through another medium.

In the second cross-section, the first channel layer 120A may be disposed to be spaced apart from the substrate 110 in a direction perpendicular to the substrate 110 (Z direction). Also, the channel 120 may include a third channel layer 120C provided to contact the source electrode 150 at one end of the first channel layer 120A in the second cross-section. In addition, the channel 120 may include a fourth channel layer 120D provided to contact the drain electrode 160 at the other end of the first channel layer 120A in the second cross-section. In the second cross-section, the channel 120 may have such a structure as having a hollow closed cross-sections, which are continuously arranged along the third direction (Z direction).

The gate insulating material 140 may be provided in the channel 120, and the gate electrode 130 may be provided in the gate insulating material 140. In the second cross-section, the gate insulating material 140 may be provided inside the channel 120, and the gate electrode 130 may be provided inside the gate insulating material 140. In the second cross-section, the channel 120 may have a structure surrounding the entire gate electrode 130. Therefore, the gate electrode 130 corresponds to the entire inner surface of the channel 120 with the gate insulating material 140 interposed therebetween.

As shown in FIG. 4, the gate electrode 130 may be spaced apart from the channel 120 with the gate insulating material 140 interposed therebetween, and may have a shape surrounding the channel 120. The gate insulating material 140 insulates between the channel 120 and the gate electrode 130 as described above, and may limit and/or suppress leakage current. The gate insulating material 140 may extend to a region between the gate electrode 130 and the source electrode 150 and between the gate electrode 130 and the drain electrode 160, so that the gate insulating material 140 may insulate between the gate electrode 130 and the source electrode 150 and between the gate electrode 130 and the drain electrode 160.

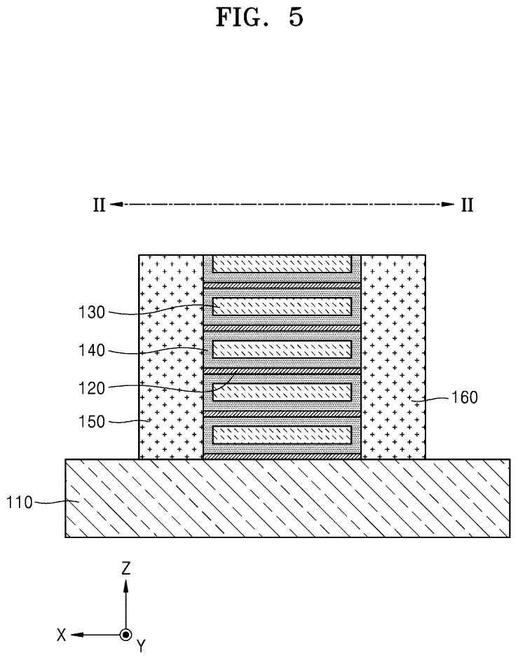

Referring to FIG. 5, the channel 120 may have a single layer structure in a second cross-section. In the second cross-section, the first channel layer 120A may be disposed to be spaced apart from the substrate 110 in a direction (Z direction) perpendicular to the substrate 110. As compared with FIG. 4, the third channel layer 120C and the fourth channel layer 120D provided to contact the source electrode 150 and the drain electrode 160 may not be included in one end and the other end of the first channel layer 120A, respectively. That is, the gate insulating material 140 may be in direct contact with the source electrode 150 and the drain electrode 160.

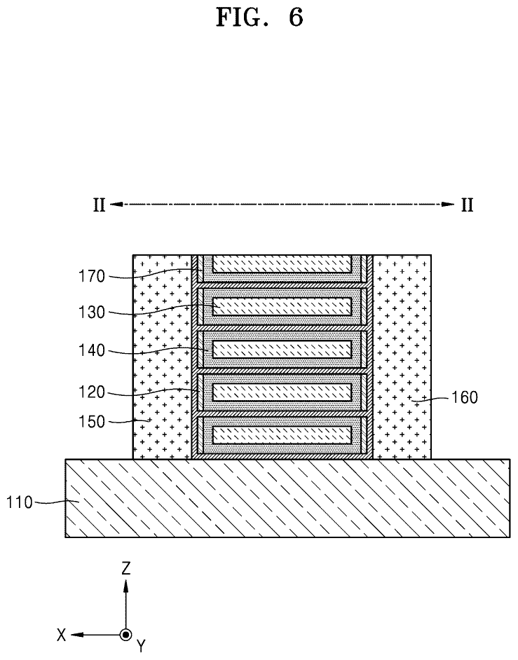

Referring to FIG. 6, a spacer 170 may be further included between the channel 120 and the gate insulating material 140. The spacer 170 may be provided between the source electrode 150 and the gate electrode 130 and between the drain electrode 160 and the gate electrode 130. The spacer 170 may be provided to insulate between the source electrode 150 and the gate electrode 130 and between the drain electrode 160 and the gate electrode 130. The spacer 170 may include an insulating material. Although insulation is possible by the gate insulating material 140, a spacer 170 may be further provided to supplement the insulating property of the gate insulating material 140.

The semiconductor device 100 according to an embodiment may employ a two-dimensional material as a material of the channel 120. The two-dimensional material refers to a semiconductor material having a two-dimensional crystal structure, and may have a monolayer or multilayer structure. Each layer constituting such a two-dimensional material may have an atomic level thickness.

The two-dimensional material has excellent electrical characteristics, and maintains high mobility without changing its characteristic, even when the thickness is reduced to nano scale, and thus, the two-dimensional material may be applied to various devices. The 2D material may include, for example, at least one of graphene, black phosphorus, and transition metal dichalcogenide. Graphene is a material that has a hexagonal honeycomb structure by two-dimensionally bonding carbon atoms, has higher electrical mobility and excellent thermal properties than silicon (Si), is chemically stable, and has a large surface area. Also, black phosphorous is a material in which black phosphorous atoms are combined in two dimensions.

TMD may include, for example, one transition metal of Mo, W, Nb, V, Ta, Ti, Zr, Hf, Tc, and Re, and one chalcogen element of S, Se, and Te. TMD may be expressed, for example, as MX2, where M represents a transition metal and X represents a chalcogen element. For example, M may be Mo, W, Nb, V, Ta, Ti, Zr, Hf, Tc, Re, etc., and X may be S, Se, Te, etc. Therefore, for example, TDM may include MoS₂, MoSe₂, MoTe₂, WS₂, WSe₂, WTe₂, ZrS₂, ZrSe₂, HfS₂, HfSe₂, NbSe₂, ReSe₂, and the like. Alternatively, TMD may not be expressed as MX2. In this case, for example, TMD may include CuS which is a compound of Cu as a transition metal and S as a chalcogen element. Meanwhile, TMD may be a chalcogenide material containing non-transition metal. The non-transition metal may include, for example, Ga, In, Sn, Ge, Pb, or the like. In this case, TMD may contain compounds of non-transforming metals such as Ga, In, Sn, Ge, and Pb and chalcogen elements such as S, Se, and Te. For example, TMD may include SnSe₂, GaS, GaSe, GaTe, GeSe, In₂Se₃, InSnS₂, and the like.

As described above, TMD may include one metal element of Mo, W, Nb, V, Ta, Ti, Zr, Hf, Tc, Re, Cu, Ga, In, Sn, Ge, and Pb, and one chalcogen element of S, Se, and Te. However, the materials mentioned above are merely exemplary, and other materials may be used as TMD materials.

The channel 120 may be made of the same two-dimensional material and may have the same thickness. However, the disclosure is not limited thereto, and the channel 120 may include different types of 2D materials and may have different thicknesses. Alternatively, the channels 120 may have a structure spaced apart from each other in cross-section, but may have a structure connected to each other like a chain in an overall three-dimensional structure.

The source electrode 150 and the drain electrode 160 may include metal material having electrical conductivity. For example, the source electrode 150 and the drain electrode 160 may include metals such as magnesium (Mg), aluminum (Al), scandium (Sc), titanium (Ti), vanadium (V), chromium (Cr), manganese (Mn), nickel (Ni), copper (Cu), zinc (Zn), gallium (Ga), zirconium (Zr), niobium (Nb), molybdenum (Mo), lead (Pd), silver (Ag), cadmium (Cd), indium (In), tin (Sn), lanthanum (La), hafnium (Hf), tantalum (Ta), tungsten (W), iridium (Ir), platinum (Pt), gold (Au), bismuth (Bi), and the like, or alloys thereof.

The gate electrode 130 may include metal material or conductive oxide. Here, the metallic material may include, for example, at least one selected from the group including (or consisting of) Au, Ti, TiN, TaN, W, Mo, WN, Pt, and Ni. The conductive oxide may include, for example, indium tin oxide (ITO), indium zinc oxide (IZO), etc. Alternatively, the gate electrode 130 may be formed of the same material as the source electrode 150 and the drain electrode 160.

The gate insulating material 140 may include a high-k dielectric material that is a material having a high dielectric constant. The gate insulating material 140 may include, for example, aluminum oxide, hafnium oxide, zirconium hafnium oxide, lanthanum oxide, or the like. However, it is not limited thereto.

The gate insulating material 140 may include ferroelectric material. The ferroelectric material has a non-centrosymmetric charge distribution in unit cells in the crystallized material structure, so that the ferroelectric material has a spontaneous electrical dipole, that is, spontaneous polarization. Therefore, the ferroelectric materials have residual polarization by dipole even in the absence of an external electric field. In addition, the direction of polarization may be changed to a domain unit by external electric field. These ferroelectric materials, for example, may include at least one oxide selected from Hf, Si, Al, Zr, Y, La, Gd, and Sr, but is exemplary. In addition, if necessary, the ferroelectric material may further include a dopant.

When the gate insulating material 140 includes ferroelectric material, the semiconductor device 100 may be applied as, for example, a logic device or a memory device. When the gate insulating material 140 includes ferroelectric material, since the subthreshold swing (SS) may be lowered by the negative capacitance effect, performance may be improved while reducing the size of the semiconductor device 100.

The gate insulating material 140 may have a multilayer structure including a high-k material and a ferroelectric material. The gate insulating material 140 includes a charge trapping layer such as silicon nitride, and etc., and thus, the semiconductor device 100 may operate as a memory transistor having memory characteristics.

The semiconductor device 100 according to an embodiment employs a two-dimensional material as a channel material, so that even if the thickness of the channel 120 is reduced to several nm or less, high electron mobility may be maintained. In addition, the semiconductor device 100 according to an embodiment adopts a corrugated channel structure, so that the effective width of the channel relative to the unit area may be large. Further, since the semiconductor device 100 according to an embodiment has the GAA structure wherein a gate electrode surrounds a channel, the on-current may increase, thereby improving the performance of the semiconductor device 100. The semiconductor device 100 according to an embodiment may be applied to various electronic devices requiring high performance and low power, such as mobile, artificial intelligence (AI), 5G communication equipment, electric field, and Internet of Things (IoT).

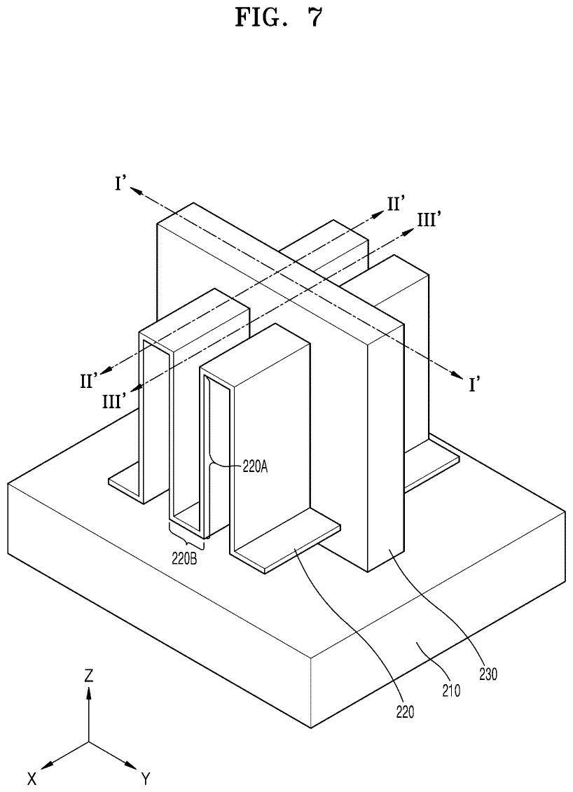

FIG. 7 is a perspective view illustrating a schematic structure of a channel and gate electrode of a semiconductor device according to another embodiment. Explanation will be given with reference to FIG. 2. Hereinafter, components with the same name as each component of the semiconductor device 100 described with reference to FIGS. 1 to 6 perform substantially the same function and operation, so the detailed description thereof will be omitted here and the differences therebetween will be mainly explained.

Referring to FIG. 7, a channel 220 may be provided on a substrate 210. In FIG. 7, the channel 220 may have a corrugated structure as similar to FIG. 2, but a direction thereof may be different. The channel 220 may include a plurality of first channel layers 220A and a plurality of second channel layers 220B. The plurality of the first channel layers 220A may be disposed to be spaced apart from each other in a direction parallel to the substrate 210. Each of the plurality of the first channel layers 220A may be provided perpendicular to one surface of the substrate 210, for example, as shown in FIG. 7. A plurality of second channel layers 220B may be provided between the plurality of first channel layers 220A. The plurality of second channel layers 220B may be provided in a direction perpendicular to the plurality of the first channel layers 220A. The plurality of the second channel layers 220B may be alternately provided at one end and the other end of the plurality of the first channel layers 220A.

A gate electrode 230 may be provided on the channel 220. The gate electrode 230 may be provided to surround the channel 220. That is, the gate electrode 230 may be provided to surround the entire side of the channel 220 including (or consisting of) the plurality of the first channel layers 220A and the plurality of the second channel layers 220B. The embodiment may also have a so-called GAA structure. All of one surface and the other surface of the plurality of the first channel layers 220A may be surrounded by the gate electrode 230, and all of the one surface and the other surface of the plurality of the second channel layers 220B may be surrounded by the gate electrode 230. For example, both the Y direction and the opposite direction of the first channel layer 220A may be surrounded by the gate electrode 230, and both the Z direction and the opposite direction of the second channel layer 220B may be surrounded by the gate electrode 230.

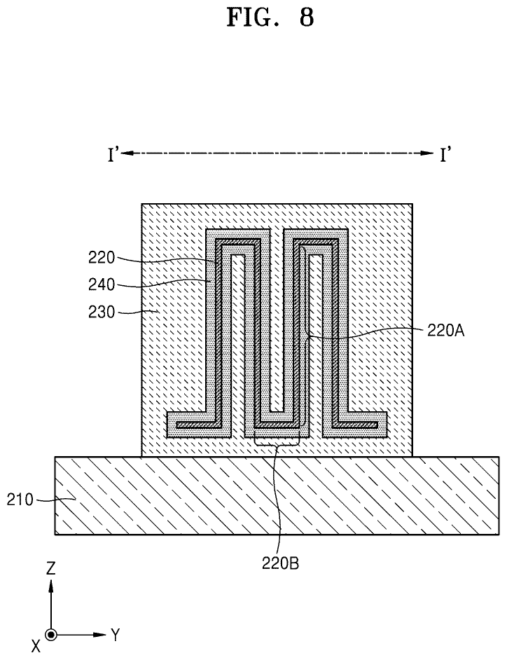

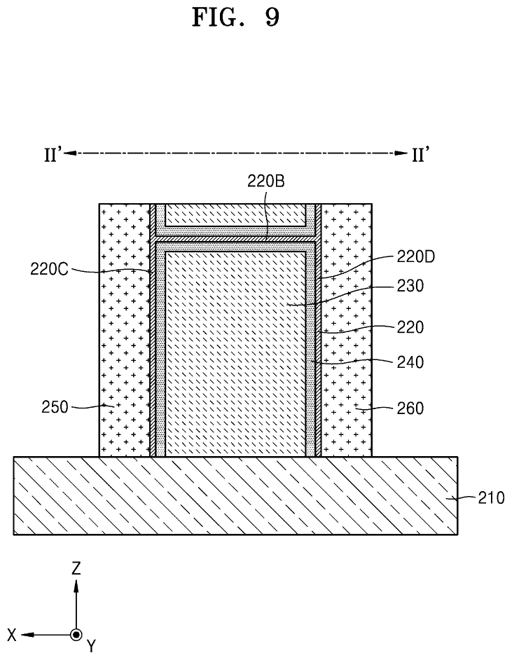

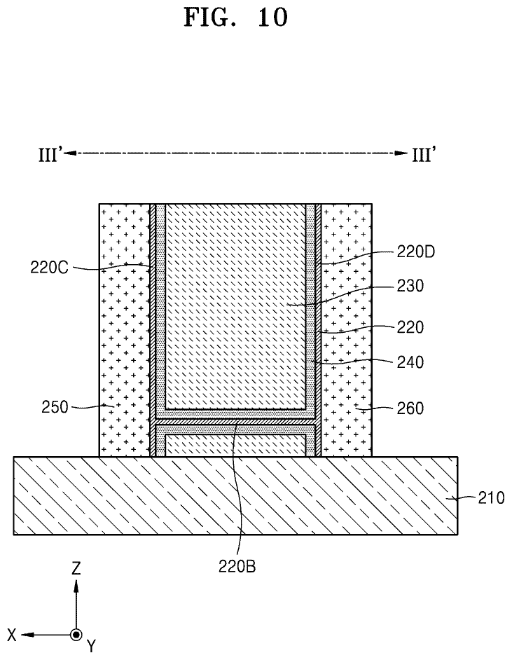

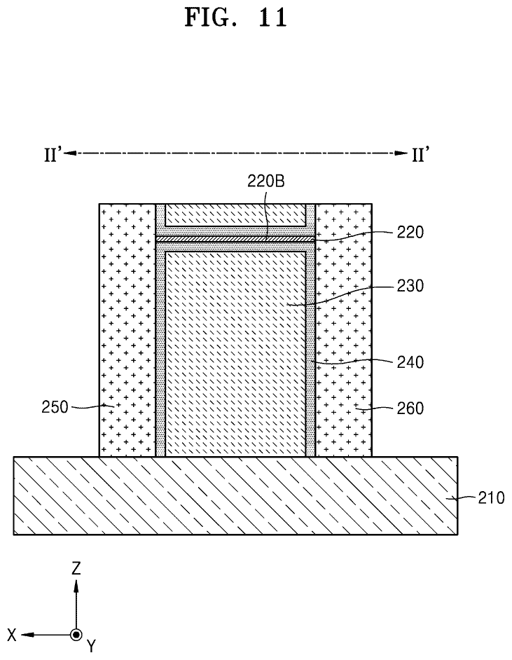

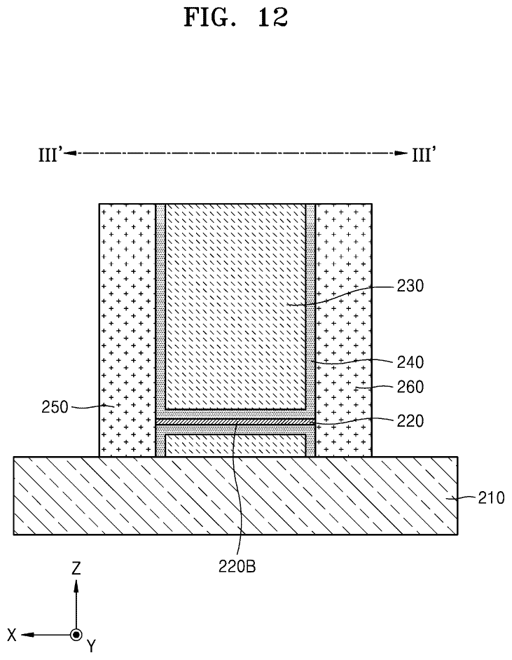

FIG. 8 is a cross-sectional view taken along the line I′-I′ of the semiconductor device of FIG. 7, FIGS. 9 and 11 are different cross-sectional views taken along the line II′-II′ of the semiconductor device of FIG. 7, and FIGS. 10 and 12 are different cross-sectional views taken along the line III′-III′ of the semiconductor device of FIG. 7. The line I′-I′ may correspond to a cross-section cut across the source electrode 250 and the drain electrode 260 (Y direction in the drawing) in a direction (Z direction in the drawing) perpendicular to the substrate 210. The cross-section denoted with the line II′-II′ may represent a cross-section cut from the source electrode 250 to the drain electrode 260 (X direction in the drawing) in a direction perpendicular to the substrate 210 (Z direction in the drawing) with respect to the second channel layer 220B provided far from the substrate 210. The cross-section denoted with the line III′-III′ may represent a cross-section cut from the source electrode 250 to the drain electrode 260 (X direction in the drawing) in a direction perpendicular to the substrate 210 (Z direction in the drawing) with respect to the second channel layer 220B provided close to the substrate 210. Here, since the substrate 210 may not be a complete plane, the vertical direction may include not only the substantial vertical direction but also the general vertical direction. Hereinafter, the description will focus on the differences from FIGS. 2 to 5.

Referring to FIG. 8, as described in FIG. 7, the channel 220 may have a corrugated structure. The plurality of the first channel layers 220A may be spaced apart from each other in the second direction (Y direction), and each of the first channel layers 220A may be provided in the direction perpendicular to the substrate 210 (Z direction). The plurality of the second channel layers 220B may be provided between the plurality of the first channel layers 220A, and the plurality of the second channel layers 220B may be provided in the direction perpendicular to the plurality of the first channel layers 220A. The plurality of the second channel layers 220B may be alternately provided at one end and the other end of the plurality of the first channel layers 220A.

Gate insulating material 240 may be provided between the channel 220 and the gate electrode 230. The gate electrode 230 may be provided on the gate insulating material 240. The gate insulating material 240 may be provided on the channel 220, and the gate electrode 230 may be provided on the gate insulating material 240.

The gate electrode 230 may surround the entire side of the channel 220 to thereby have a GAA structure. The gate insulating material 240 may be provided between the channel 220 and the gate electrode 230. The gate electrode 230 may be provided on the gate insulating material 240. The gate electrode 230 may be provided on both surfaces of the first channel layer 220A and both surfaces of the second channel layer 220B with the gate insulating material 240 interposed therebetween.

Referring to FIGS. 9 and 10, the channel 220 may be connected between the source electrode 250 and the drain electrode 260 to become a path through which current flows between the source electrode 250 and the drain electrode 260. The channel 220 may be in direct contact with the source electrode 250 and the drain electrode 260. However, the channel 220 is not limited hereto, and it is also possible for the channel 220 to be connected to the source electrode 250 and drain electrode 260 through another medium.

The second channel layer 220B may be spaced apart from the substrate 210 in a direction perpendicular to the substrate 210 (Z direction). The channel 220 may include a third channel layer 220C provided at one end of the second channel layer 220B to contact the source electrode 250. Gate insulating material 240 may be provided inside the channel 220, and a gate electrode 230 may be provided inside the gate insulating material 240. The channel 220 may include a fourth channel layer 220D provided at the other end of the second channel layer 220B to contact the drain electrode 260. In addition, the second channel layer 220B of FIG. 9 may be provided farther from the substrate 210 than the second channel layer 220B of FIG. 10, and the second channel layer 220B of FIG. 10 may be provided closer to the substrate 210 than the second channel layer 220B of FIG. 9.

Referring to FIGS. 11 and 12, the second channel layer 220B of FIG. 11 may be farther from the substrate 210 than the second channel layer 220B of FIG. 12, and the second channel layer 220B of FIG. 11 may be closer to the substrate 210 than the second channel layer 220B of FIG. 12. In FIGS. 11 and 12, compared to FIGS. 9 and 10, the third channel layer 220C and the fourth channel layer 220D provided to contact the source electrode 250 and the drain electrode 260 may not be included at one end and the other end of the second channel layer 220B, respectively. That is, the gate insulating material 240 may be in direct contact with the source electrode 250 and the drain electrode 260.

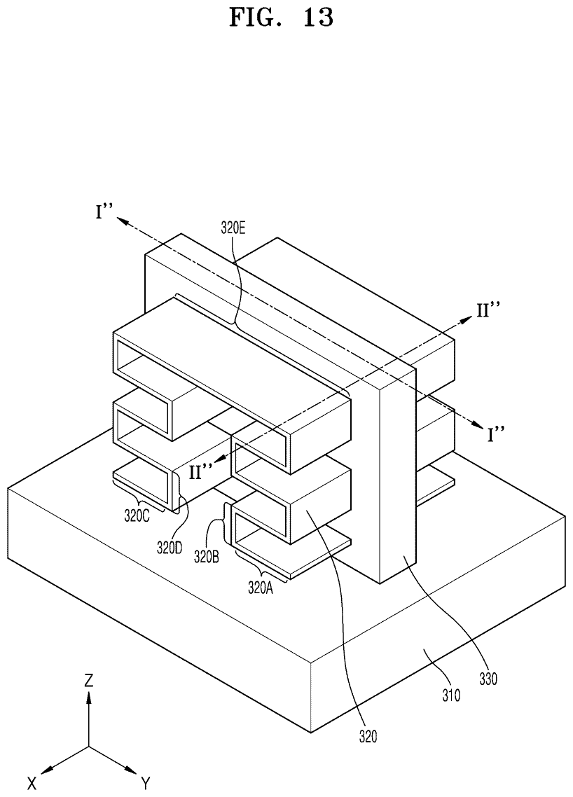

FIG. 13 illustrates a semiconductor device according to another embodiment. The difference from FIG. 2 will be described.

Referring to FIG. 13, a channel 320 may have a corrugated structure. The channel 320 may include a plurality of first channel layers 320A, a plurality of second channel layers 320B, a plurality of third channel layers 320C, a plurality of fourth channel layers 320D, and a central channel layer 320E.

The plurality of the first channel layers 320A and the plurality of the third channel layers 320C may be provided symmetrically with respect to the center of the central channel layer 320E. Each of the plurality of the first channel layers 320A may be spaced apart from each other with a predetermined interval in the second direction (Y direction) with respect to the center of the central channel layer 320E. Each of the plurality of the third channel layers 320C may be spaced apart from each other with a predetermined interval in a direction opposite to the second direction (Y direction) with respect to the center of the central channel layer 320E. The plurality of the first channel layers 320A may be spaced apart from each other in the third direction (Z direction), and the plurality of the third channel layers 320C may be spaced apart from each other in the third direction (Z direction). The plurality of the first channel layers 320A and the plurality of the third channel layers 320C may be provided at approximately same level to each other in the third direction (Z direction).

Each of the plurality of the second channel layers 320B and 320D may be provided between the plurality of the first channel layers 320A, and the plurality of the second channel layers 320B and 320D may be provided in a direction perpendicular to the plurality of the first channel layers 320A and 320C. The plurality of the second channel layers 320B may be alternately provided at one end and the other end of the plurality of the first channel layers 320A, and the plurality of the fourth channel layers 320D may be alternately provided at one end and the other end of the plurality of third channel layers 320C. The plurality of the second channel layers 320B and the plurality of the fourth channel layers 320D may be provided symmetrically with respect to the center of the central channel layer 320E.

The channel 320 may include a 2D material. The two-dimensional material may include graphene, black phosphorus, phosphorine, transition metal dichalcogenide, or a combination thereof. The transition metal dichalcogenide may include one metal element selected from the group including (or consisting of) Mo, W, Nb, V, Ta, Ti, Zr, Hf, Tc, Re, Cu, Ga, In, Sn, Ge, and Pb, and one chalcogen element selected from the group including (or consisting of) S, Se, and Te. For example, the two-dimensional material may include MoS₂, MoSe₂, MoTe₂, WS₂, or a combination thereof. The two-dimensional material may have a band gap of 0.1 eV or more.

The gate electrode 330 may surround the entire side of the channel 320 to thereby have a GAA structure. The gate electrode 330 may be provided on both surfaces of the first channel layer 320A, the second channel layer 320B, the third channel layer 320C, and the fourth channel layer 320D.

In FIG. 13, the first channel layer 320A closest to the substrate 310 among the plurality of first channel layers 320A and the third channel layer 320C closest to the substrate 310 among the plurality of the third channel layers 320C are spaced apart from the substrate 310 with a predetermined distance, but the first channel layer 320A and the third channel layer 320C closest to the substrate 310 may be provided to contact the substrate 310. In this case, the gate electrode 330 may be provided only on one of both surfaces of the first channel layer 320A closest to the substrate 310 among the plurality of the first channel layers 320A and only one of both surface of the third channel layer 320C closest to the substrate 310 among the plurality of third channel layers 320C.

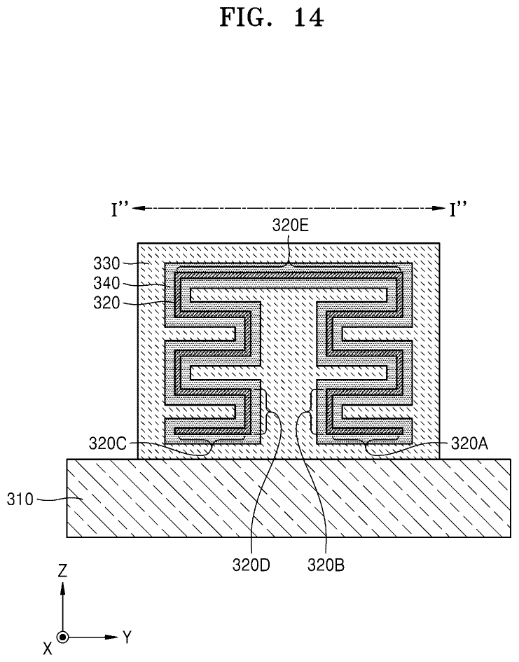

FIG. 14 is a cross-sectional view taken along line I″-I″ of the semiconductor device of FIG. 13.

Referring to FIG. 14, as described with reference to FIG. 13, the channel 320 may have a corrugated structure. The channel 320 may include a plurality of first channel layers 320A, a plurality of second channel layers 320B, a plurality of third channel layers 320C, a plurality of fourth channel layers 320D, and a central channel layer 320E.

Each of the plurality of second channel layers 320B may be provided between the plurality of the first channel layers 320A, and the plurality of the second channel layers 320B may be provided in a direction perpendicular to the plurality of the first channel layers 320A. The plurality of the second channel layers 320B may be alternately provided at one end and the other end of the plurality of the first channel layers 320A. The length of the first channel layer 320A may be longer than the length of the second channel layer 320B. For example, the length of the first channel layer 320A may be approximately 2 nm to 500 nm. Alternatively, the length of the first channel layer 320A may be approximately 5 nm to 250 nm. For example, the length of the second channel layer 320B may be approximately 1 nm to 50 nm. Alternatively, the length of the second channel layer 320B may be 1 nm to 25 nm.

Each of the plurality of the fourth channel layers 320D may be provided between the plurality of the third channel layers 320C, and the plurality of the fourth channel layers 320D may be provided in a direction perpendicular to the plurality of the third channel layers 320C. The plurality of the fourth channel layers 320D may be alternately provided at one end and the other end of the plurality of the third channel layers 320C. The length of the third channel layer 320C may be longer than the length of the second channel layer 320B. For example, the length of the third channel layer 320C may be approximately 2 nm to 500 nm. Alternatively, the length of the third channel layer 320C may be approximately 5 nm to 250 nm. For example, the length of the fourth channel layer 320D may be approximately 1 nm to 50 nm. Alternatively, the length of the fourth channel layer 320D may be 1 nm to 25 nm.

The gate electrode 330 may surround the entire side of the channel 320 to thereby have a GAA structure. The gate insulating material 340 may be provided between the channel 320 and the gate electrode 330. The gate electrode 330 may be provided on the gate insulating material 340. The gate electrode 330 may be provided on both surfaces of the first channel layer 320A, the second channel layer 320B, the third channel layer 320C, the fourth channel layer 320D, and the central channel layer 320E, with the gate insulating material 340 interposed therebetween.

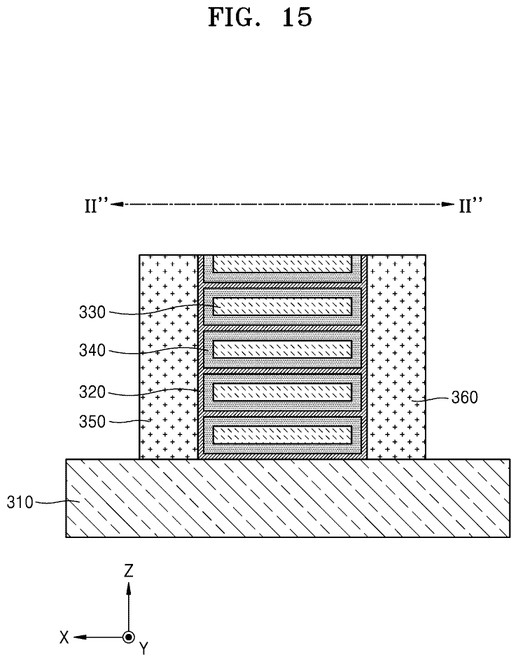

FIGS. 15 to 17 are cross-sectional views of the semiconductor device of FIG. 13, which are differently shown with II″-II″.

Referring to FIG. 15, in the cross-section denoted with II″-II″ of FIG. 13, the substrate 310, the channel 320, the gate electrode 330, the gate insulating material 340, the source electrode 350, and the drain electrode 360 of FIG. 15 may be the same as or similar to the substrate 110, the channel 120, the gate electrode 130, the gate insulating material 140, the source electrode 150, and the drain electrode 160 of FIG. 4.

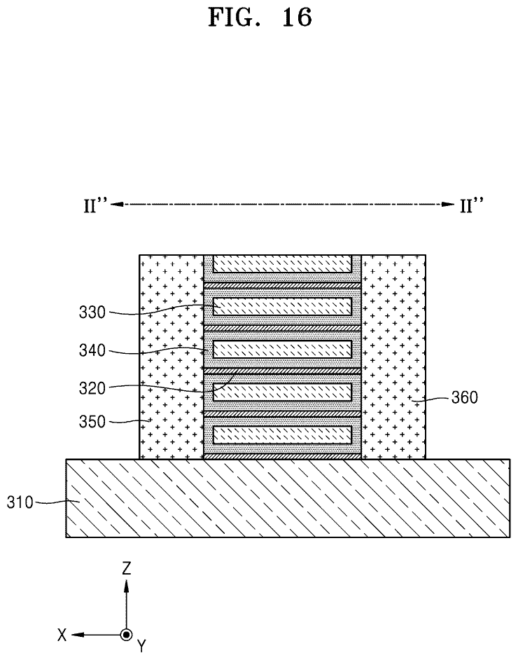

Referring to FIG. 16, in the cross-section denoted with II″-II″ of FIG. 13. The substrate 310, the channel 320, the gate electrode 330, the gate insulating material 340, the source electrode 350, and the drain electrode 360 of FIG. 16 may be the same as or similar to the substrate 110, the channel 120, the gate electrode 130, the gate insulating material 140, the source electrode 150, and the drain electrode 160 of FIG. 4

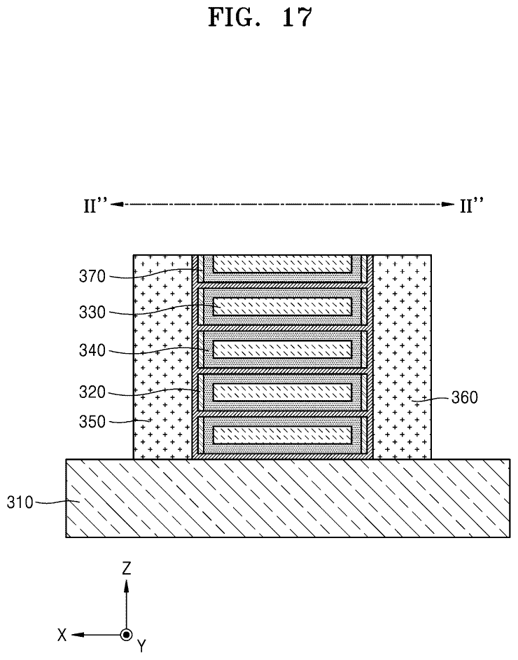

Referring to FIG. 17, in the cross-section denoted with II″-II″ of FIG. 13, the substrate 310, the channel 320, the gate electrode 330, the gate insulating material 340, the source electrode 350, the drain electrode 360, and the spacer 370 of FIG. 16 may be the same as or similar to the substrate 110, the channel 120, the gate electrode 130, the gate insulating material 140, the source electrode 150, the drain electrode 160, and the spacer 170 of FIG. 4.

Next, a method of manufacturing a semiconductor device according to an embodiment will be described. For convenience, the method will be described based on FIG. 3.

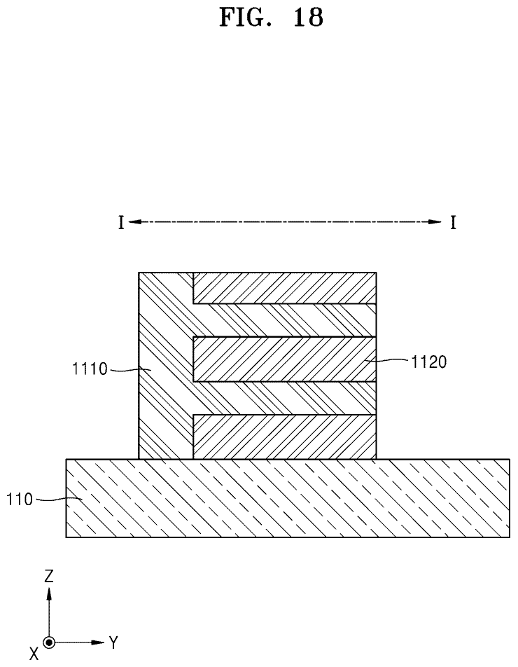

Referring to FIG. 18, a first sacrificial layer 1110 and a second sacrificial layer 1120 may be alternately stacked and patterned on a substrate 110. The substrate 110 may be an insulated substrate, or a semiconductor substrate having an insulating layer formed on a surface thereof. The semiconductor substrate may include, for example, a Si, Ge, SiGe, or a group III-V semiconductor material. The substrate 110 may be, for example, a silicon substrate having a silicon oxide formed on a surface thereof, but is not limited thereto. The first sacrificial layer 1110 and the second sacrificial layer 1120 may be formed of materials that may be selectively removed according to an etching gas or an etching solution. The first sacrificial layer 1110 may include nitrogen, and the second sacrificial layer 1120 may include oxygen.

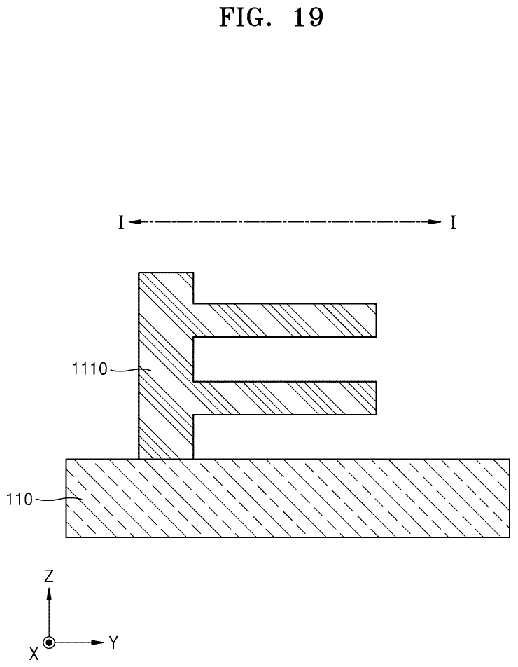

Referring to FIG. 19, after the source electrode 150 and the drain electrode 160 are formed, only the second sacrificial layer 1120 is selectively removed and only the first sacrificial layer 1110 is left.

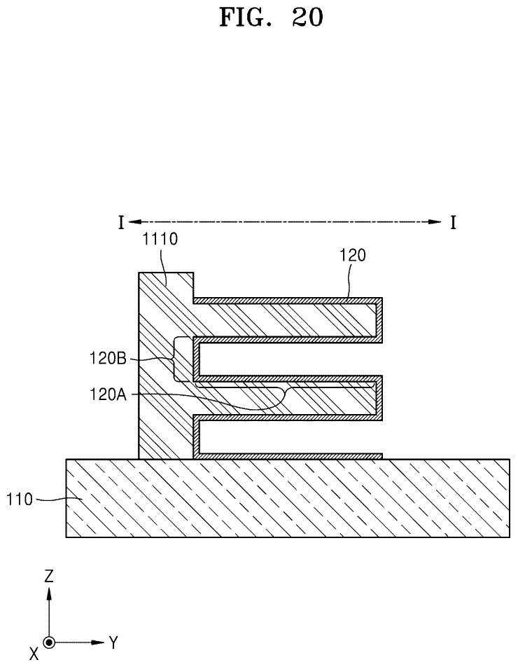

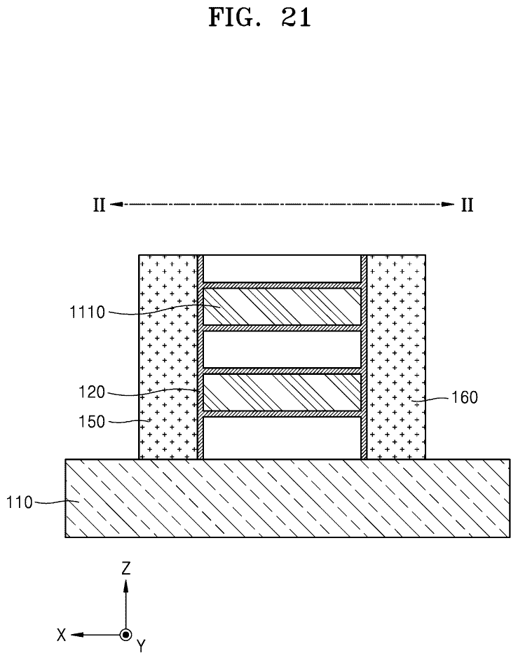

Referring to FIG. 20, a channel 120 may be deposited on the first sacrificial layer 1110. The channel 120 may be formed by Chemical Vapor Deposition (CVD), Metal Organic Chemical Vapor Deposition (MOCVD), or Atomic Layer Deposition (ALD) processes. The channel 120 includes a plurality of first channel layers 120A and a plurality of second channel layers 120B, and the plurality of the second channel layers 120B may be perpendicular to the plurality of the first channel layers 120A between the plurality of first channel layers 120A. The second channel layer 120B may be alternately provided at one end and the other end of the plurality of the first channel layers 120A. A plurality of first channel layers 120A may be disposed in parallel with the substrate 110 as shown in FIG. 3. Alternatively, the plurality of the first channel layers 120A may be provided perpendicular to the substrate 110 as illustrated in FIG. 8. The channel 120 may be formed of, for example, two-dimensional material. The two-dimensional material may include graphene, black phosphorus, phosphorine, transition metal dichalcogenide, or a combination thereof. The transition metal dichalcogenide may include one metal element selected from the group including (or consisting of) Mo, W, Nb, V, Ta, Ti, Zr, Hf, Tc, Re, Cu, Ga, In, Sn, Ge, and Pb, and one chalcogen element selected from the group including (or consisting of) S, Se, and Te. For example, the two-dimensional material may include MoS₂, MoSe₂, MoTe₂, WS₂, or a combination thereof. The two-dimensional material may have a band gap of 0.1 eV or more. The two-dimensional material may be deposited to have a thickness of several nanometers. When the channel is formed of 2D material, it may be difficult to form the channel because the channel has very thin thickness, but by forming the channel 120 in the first sacrificial layer 1110 as in the embodiment, the 2D material may be deposited thinly with ease. The first sacrificial layer 1110 may serve to support the channel 120. In this case, after the channel 120 is formed in the first sacrificial layer 1110, the channel 120 may be additionally formed at both ends of the channel 120 in the first direction (X direction), and the source electrode 140 and the drain electrode 160 may be formed as shown in FIG. 21.

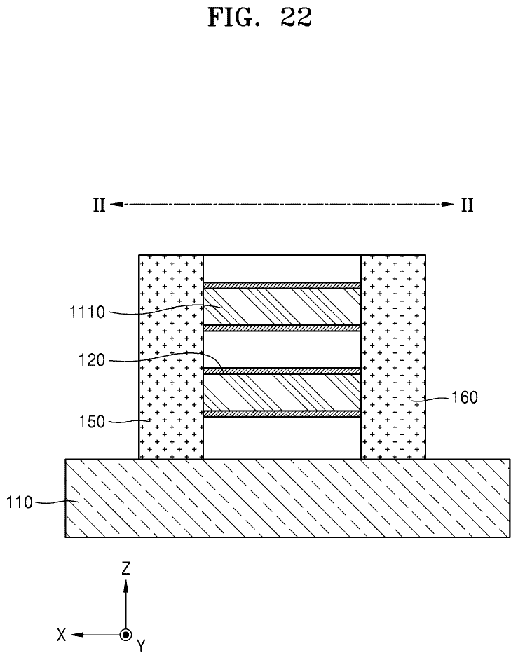

Alternatively, as shown in FIG. 22, the source electrode 150 and the drain electrode 160 may be formed without additionally forming the channel 120 at both ends of the channel 120 in the first direction (X direction).

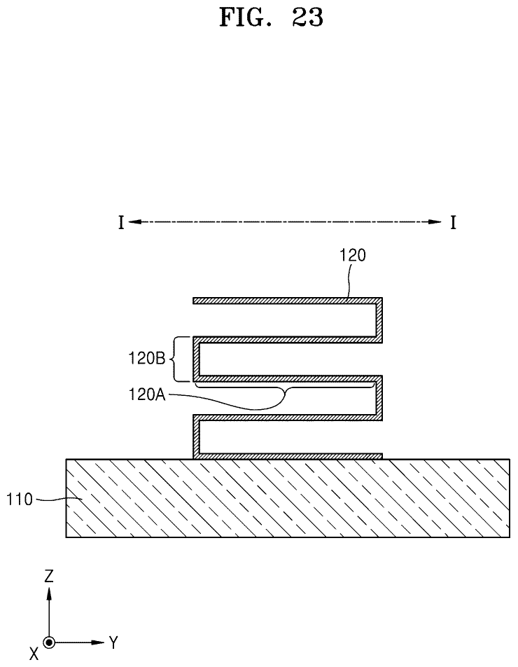

Referring to FIGS. 20 and 23, the first sacrificial layer 1110 may be selectively removed and the channel 120 may be left. In this case, even if the first sacrificial layer 1110 is removed, the channel 120 may be supported by the source electrode 150 and the drain electrode 160.

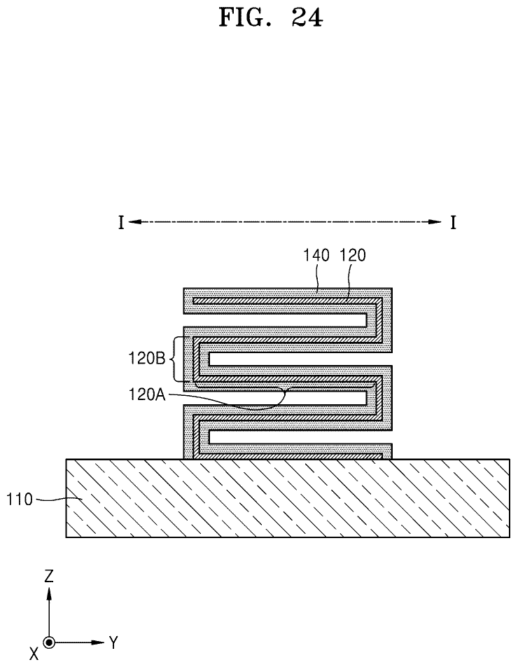

Referring to FIG. 24, the gate insulating material 140 may be deposited on the channel 120. The gate insulating material 140 may be deposited by CVD, MOCVD, or ALD methods.

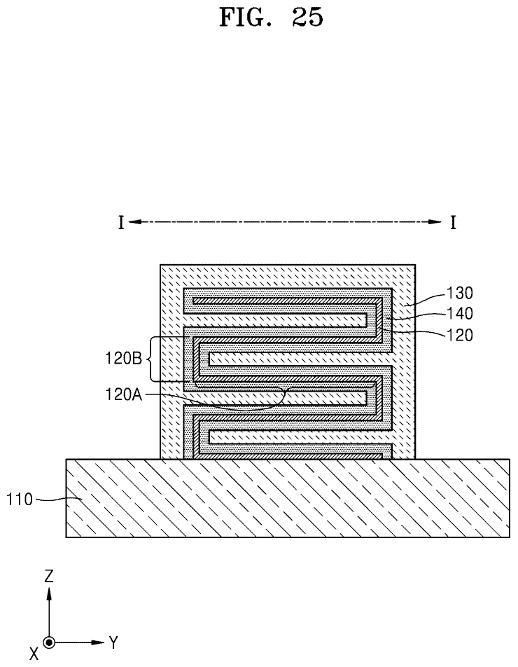

Referring to FIG. 25, a gate electrode 130 may be deposited on the gate insulating material 140. The gate electrode 130 may be provided on the one surface and the other surface of the plurality of first channel layers 120A, and the one surface and the other surface of the plurality of second channel layers 120B with the gate insulating material 140 interposed therebetween. For example, both the Z-axis direction and the opposite direction of the first channel layer 120A may be surrounded by the gate electrode 130, and both the Y-axis direction and the opposite direction of the second channel layer 120B may be surrounded by the gate electrode 130.

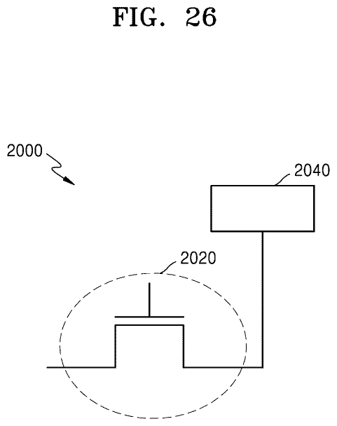

FIG. 26 illustrates an electronic device 2000 according to an embodiment. In an example, the electronic device 2000 may be a memory device.

Referring to FIG. 26, the electronic device 2000 includes a switching device 2020 and a data storage unit 2040 connected thereto. In an example, the switching device 2020 may include a semiconductor device. In an example, the switching device 2020 may include one of the semiconductor devices according to the above-described embodiments. In one example, the data storage unit 2040 may include a data storage unit used in volatile or nonvolatile memory devices. The data storage unit 2040 may include a capacitor, and may include a magnetoresistive layer or a phase change layer.

Next, an electronic device(s) according to an embodiment will be described. The electronic device(s) according to an embodiment may include a semiconductor device or an electronic device according to the above-described embodiments.

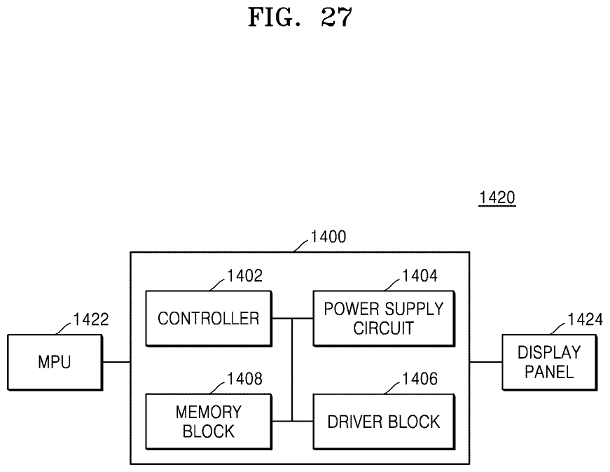

FIG. 27 is an electronic device according to an embodiment, and is a schematic block diagram of a display device 1420 including a display driver integrated circuit (DDI) 1400 and a DDI 1400.

Referring to FIG. 27, the DDI 1400 may include a controller 1402, a power supply circuit 1404, a driver block (e.g., driver circuit) 1406, and a memory block 1408. The controller 1402 receives and decodes a command applied from a main processing unit (MPU) 1422, and controls each block of the DDI 1400 to implement an operation according to the command. The power supply circuit 1404 generates a driving voltage in response to the control of the controller 1402. The driver block 1406 drives a display panel 1424 using the driving voltage generated by the power supply circuit 1404 in response to the control of the control unit 1402. The display panel 1424 may be a liquid crystal display panel or a plasma display panel. The memory block 1408 is a block for temporarily storing commands input to the control unit 1402 or control signals output from the control unit 1402 or storing necessary data, and may include a volatile memory (e.g., RAM) and/or a nonvolatile memory. In an example, the control unit 1402 may include an electronic device (e.g., the electronic device 2000 of FIG. 26) according to the above-described embodiment. In an example, the portions and/or blocks included in the DDI 1400 may include a switching device, and the switching device may include one of the semiconductor devices according to the above-described embodiments. For example, the memory block 1408 may include the electronic device 2000 in FIG. 26.

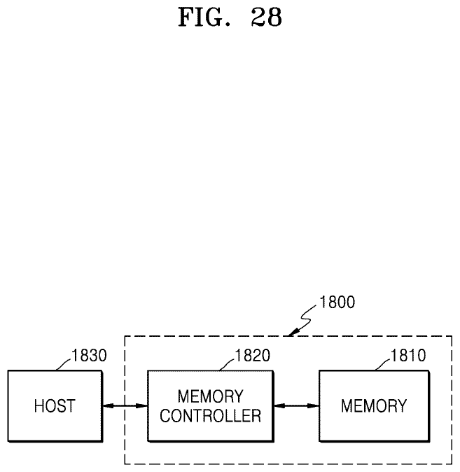

FIG. 28 is a block diagram illustrating an electronic system 1800 as an electronic device according to another embodiment.

Referring to FIG. 28, an electronic system 1800 includes a memory 1810 and a memory controller 1820. The memory controller 1820 may control the memory 1810 for reading data from the memory 1810 and/or writing data to the memory 1810 in response to a request from the host 1830.

In an example, the memory 1810 may include an electronic device (e.g., the electronic device 2000 of FIG. 26) according to the above-described embodiment. In an example, the memory 1810 and the memory controller 1820 of the electronic system 1800 may include a switching device, and the switching device may include one of the semiconductor devices according to the above-described embodiments.

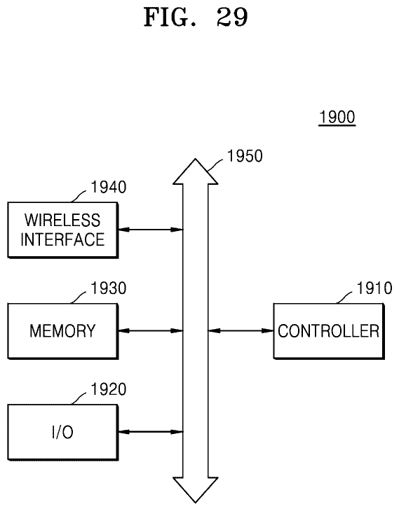

FIG. 29 is an electronic device according to another embodiment, and is a block diagram of an electronic system 1900.

Referring to FIG. 29, the electronic system 1900 may configure a wireless communication device or a device capable of transmitting and/or receiving information under a wireless environment. The electronic system 1900 includes a controller 1910, an input/output device (I/O) 1920, a memory 1930, and a wireless interface 1940, each of which is interconnected via a bus 1950.

The controller 1910 may include at least one of a microprocessor, a digital signal processor, or a processing device similar thereto. The input/output device 1920 may include at least one of a keypad, a keyboard, or a display.

The memory 1930 may be used to store instructions executed by the controller 1910. For example, the memory 1930 may be used to store user data. In one example, the memory 1930 may include an electronic device (e.g., the electronic device 2000 of FIG. 26) according to the above-described embodiment.

In one example, the components 1910, 1920, 1930, and 1940 included in the electronic system 1900 may include a switching device, and the switching device may include one of the semiconductor devices according to the above-described embodiments.

The electronic system 1900 may use a wireless interface 1940 to transmit/receive data through a wireless communication network. The wireless interface 1940 may include an antenna and/or a wireless transceiver. In some embodiment, the electronic systems 1900 may be used in a third generation communication system, for example, in a communication interface protocol of the third generation communication system, such as CDMA (code division multiple access), GSM (global system for mobile communications), NADC (north American digital cellular), E-TDMA (extended-time division multiple access), and/or WCDMA (wide band code division multiple access).

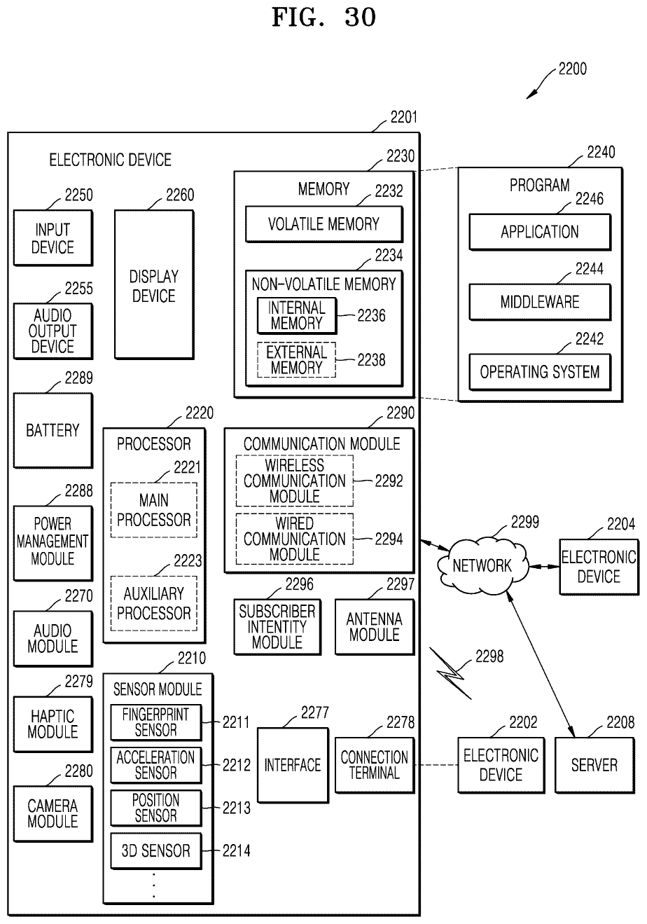

FIG. 30 is a block diagram illustrating a schematic configuration of an electronic device according to another embodiment.

Referring to FIG. 30, in the network environment 2200, an electronic device 2201 may communicate with another electronic device 2202 through a first network 2298 (a short-range wireless communication network, etc.), or with another electronic device 2204 and/or a server 2208 through a second network 2299 (a long-range wireless communication network, etc.). The electronic device 2201 may communicate with the electronic device 2204 through the server 2208. The electronic device 2201 may include a processor 2220, a memory 2230, an input device 2250, an audio output device 2255, a display device 2260, an audio module 2270, a sensor module 2210, an interface 2277, a haptic module 2279, a camera module 2280, a power management module 2288, a battery 2289, a communication module 2290, a subscriber identification module 2296, and/or an antenna module 2297. Some of these components (such as the display device 2260) may be omitted or other components may be added to the electronic device 2201. Some of these components may be implemented as one integrated circuit. For example, a fingerprint sensor 2211 of the sensor module 2210, an iris sensor or an illuminance sensor, etc. may be implemented as an embedded form in the display device 2260 (display, etc.).

The processor 2220 may execute software (program 2240 or the like) to control one or other plural components (hardware, software components, etc.) of the electronic device 2201 connected to the processor 2220, and may perform various data processing or operation. As part of data processing or operation, the processor 2220 may load commands and/or data received from other components (sensor module 2210, communication module 2290, etc.) into a volatile memory 2232, process the commands and/or data stored in the volatile memory 2232, and store the result data in a nonvolatile memory 2234. The processor 2220 may include a main processor 2221 (a central processing unit, an application processor, etc.) and an auxiliary processor 2223 (a graphic processing unit, an image signal processor, a sensor hub processor, a communication processor, etc.) that may be operated independently or together with the main processor. The auxiliary processor 2223 uses less power than the main processor 2221 and may perform a specialized function.

The auxiliary processor 2223 may control functions and/or states related to some of the components of the electronic device 2201 (a display device 2260, the sensor module 2210, the communication module 2290, etc.) on behalf of the main processor 2221 while the main processor 2221 is in an inactive state (a state of sleeping), or along with the main processor 2221 while the main processor 2221 is in an active state (a state of executing the application). The auxiliary processor 2223 (image signal processor, communication processor, etc.) may be implemented as part of other functionally related components (camera module 2280, communication module 2290, etc.).

The memory 2230 may store various data required by components of the electronic device 2201 (the processor 2220, sensor module 2276, etc.). The data may include, for example, software (such as program 2240) and input data and/or output data for commands related thereto. The memory 2230 may include the volatile memory 2232 and/or the nonvolatile memory 2234. The nonvolatile memory 2234 may include the internal memory 2236 and the external memory 2238. In one example, the memory 2230 may include an electronic device (e.g., the electronic device 2000 of FIG. 26) according to the above-described embodiment.

The program 2240 may be stored as the software in the memory 2230, and may include the operating system 2242, the middleware 2244 and/or the application 2246.

The input device 2250 may receive commands and/or data to be used for components (the processor 2220 or the like) of the electronic device 2201 from the outside of the electronic device 2201 (user or the like). The input device 2250 may include the microphone, the mouse, the keyboard, and/or the digital pen (such as the stylus pen).

The sound output device 2255 may output the sound signal to the outside of the electronic device 2201. The sound output device 2255 may include the speaker and/or the receiver. The speaker may be used for general purposes, such as the multimedia playback or recording the playback, and the receiver may be used to receive the incoming telephone calls. The receiver may be coupled as the part of the speaker or implemented as the separate device that is independent.

The display device 2260 may visually provide information to the outside of the electronic device 2201. The display device 2260 may include a display, a hologram device, a projector and a control circuit for controlling the corresponding device. The display device 2260 may include the touch circuit set to sense the touch, and/or the sensor circuit set to measure the strength of the force generated by the touch (such as a pressure sensor).

The audio module 2270 may convert sound into the electrical signal, or conversely convert the electrical signal into sound. The audio module 2270 may acquire sound through the input device 2250, or output sound through the speaker and/or the headphone of another electronic device (such as the electronic device 2202) connected directly or wirelessly to the sound output device 2255, and/or the electronic device 2201.

The sensor module 2210 may detect the operating state (power, temperature, etc.) of the electronic device 2201 or the external environmental state (user state, etc.), and generate electrical signal and/or data value corresponding to the detected state. The sensor module 2210 may include the fingerprint sensor 2211, the acceleration sensor 2212, the position sensor 2213, the 3D sensor 2214, and in addition to this, may include the iris sensor, the gyro sensor, the atmospheric pressure sensor, the magnetic sensor, the grip sensor, the proximity sensor, the color sensor, the Infused (IR) sensor, the biometric sensor, the temperature sensor, the humidity sensor, and/or the illuminance sensor.

The 3D sensor 2214 senses the shape and movement of the subject by irradiating the predetermined light to the subject and analyzing the light reflected from the subject, and may include the meta-optical element.

The interface 2277 may support the one or more designated protocols that may be used for the electronic device 2201 to be connected directly or wirelessly to another electronic device (such as the electronic device 2202). The interface 2277 may include a High Definition Multimedia Interface (HDMI), a Universal Serial Bus (USB) interface, an SD card interface, and/or an audio interface.

A connection terminal 2278 may include a connector through which the electronic device 2201 may be physically connected to another electronic device (such as the electronic device 2202). The connection terminal 2278 may include the HDMI connector, the USB connector, the SD card connector, and/or the audio connector (such as the headphone connector).

A haptic module 2279 may convert an electrical signal into a mechanical stimulus (vibration, motion, etc.) or an electrical stimulus that a user may perceive through a tactile or motor sense. The haptic module 2279 may include the motor, the piezoelectric element, and/or the electrical stimulation device.

The camera module 2280 may photograph the still image and the moving image. The camera module 2280 may include a lens assembly including one or more lenses, image sensors, image signal processors, and/or flashes. The lens assembly included in the camera module 2280 may collect light emitted from the subject that is a target of image capturing.

The power management module 2288 may manage the power supplied to the electronic device 2201. The power management module 2288 may be implemented as the part of the power management integrated circuit (PMIC).

The battery 2289 may supply the power to components of the electronic device 2201. The battery 2289 may include the non-rechargeable primary battery, the rechargeable secondary battery, and/or the fuel cell.

The communication module 2290 may support establishment of a direct (wired) communication channel and/or a wireless communication channel between the electronic device 2201 and another electronic device (the electronic device 2202, the electronic device 2204, a server 2208, etc.), and communication through the established communication channel. The communication module 2290 may include one or more communication processors that operate independently of the processor 2220 (such as an application processor) and support direct communication and/or wireless communication. The communication module 2290 may include a wireless communication module 2292 (a cellular communication module, a short-range wireless communication module, a global navigation satellite system (GNSS, etc.) communication module and/or a wired communication module 2294 (LAN (local area network) communication module), a power line communication module, etc.). Among these communication modules, the corresponding communication module may communicate with other electronic devices through the first network 2298 (a short-range communication network such as Bluetooth, WiFi Direct or IrDA (infrared data association) or the second network 2299 (a cellular network, the Internet, or a remote communication network such as a computer network (LAN, WAN, etc.). These various types of communication modules may be integrated into one component (such as a single chip) or implemented as a plurality of separate components (such as a plurality of chips). The wireless communication module 2292 may verify and authenticate the electronic device 2201 in a communication network such as the first network 2298 and/or the second network 2299 using subscriber information (such as an international mobile subscriber identifier (IMSI) or the like) stored in the subscriber identification module 2296.

The antenna module 2297 may transmit or receive signals and/or power to or from the outside (such as other electronic devices). The antenna may include a radiator formed of a conductive pattern formed on a substrate (PCB or the like). The antenna module 2297 may include one or a plurality of antennas. When a plurality of antennas are included, an antenna suitable for a communication method used in a communication network such as the first network 2298 and/or the second network 2299 may be selected from among a plurality of antennas by the communication module 2290. Signals and/or power may be transmitted or received between the communication module 2290 and other electronic devices via the selected antenna. In addition to the antenna, other components (such as RFIC) may be included as a part of the antenna module 2297.

Some of the components are connected to each other and can exchange signals (command, data, etc.) through communication methods between peripheral devices (Bus, General Purpose Input and Output (GPIO), Serial Peripheral Interface (SPI), Mobile Industry Processor Interface (MIPI, etc.)).

A command or data may be transmitted or received between the electronic device 2201 and the external electronic device 2204 through the server 2208 connected to the second network 2299. The other electronic devices 2202 and 2204 may be the same or different type of devices as the electronic device 2201. All or some of the operations executed in the electronic device 2201 may be executed in one or more of the other electronic devices 2202, 2204, and 2208. For example, when the electronic device 2201 needs to perform a function or a service, the electronic device 2201 may ask one or more other electronic devices to perform part or all of the function or the service, instead of executing the function or the service on their own. The one or more other electronic devices receiving the request may execute an additional function or service related to the request, and transmit a result of the execution to the electronic device 2201. To this end, the cloud computing, distributed computing, and/or client-server computing technologies may be used.

In the network environment 2200, at least the electronic device 2201 may include a switching device (e.g., a semiconductor device), and the switching device may include one of the semiconductor devices according to the above-described embodiments.

Although many items are specifically described in the above description, they should be interpreted as non-limiting example embodiments rather than limiting the scope of the disclosure. Therefore, the scope of the disclosure should not be determined by the described embodiments, but should be determined by technical ideas described in the claims.

The semiconductor device according to an embodiment may exhibit good electrical performance with a micro-structure, and thus may be applied to an integrated circuit device, and may realize miniaturization, low power, and high performance.

A semiconductor device including a two-dimensional material according to an embodiment may increase electron mobility by including a channel including a two-dimensional material, and may increase gate controllability, because the gate electrode has a structure surrounding the entire surface of the channel.

A method of manufacturing a semiconductor device including a two-dimensional material according to an embodiment provides a method of manufacturing a thin channel with each.

Any or all of the elements described with reference to FIGS. 27 and 30 may communicate with any or all other elements described with reference to FIGS. 27 and 30. For example, in FIG. 30, any element may engage in one-way and/or two-way and/or broadcast communication with any or all other elements in FIG. 30, to transfer and/or exchange and/or receive information such as but not limited to data and/or commands, in a manner such as in a serial and/or parallel manner, via a bus such as a wireless and/or a wired bus (not illustrated). The information may be in encoded various formats, such as in an analog format and/or in a digital format.

One or more of the elements disclosed above may include or be implemented in processing circuitry such as hardware including logic circuits; a hardware/software combination such as a processor executing software; or a combination thereof. For example, the processing circuitry may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A semiconductor device, comprising:
a substrate;
a source electrode and a drain electrode spaced apart from each other on the substrate;
a channel between the source electrode and the drain electrode, the channel including a two-dimensional material; and
a gate electrode between the source electrode and the drain electrode, wherein
the channel includes a plurality of first channel layers and a plurality of second channel layers,
the plurality of the first channel layers are parallel to each other and spaced apart from each other,
the plurality of the second channel layers are perpendicular to the plurality of the first channel layers and between the plurality of the first channel layers,
the plurality of second channel layers, respectively, are alternately provided at a first end of each of the plurality of the first channel layers and a second end of each of the plurality of the first channel layers, and
the gate electrode is on a first surface of each of the plurality of first channel layers and a second surface of each of the plurality of first channel layers, and
the gate electrode is on a first surface of each of the plurality of second channel layers and a second surface of each of the plurality of second channel layers.

2. The semiconductor device of claim 1, wherein gate insulation material is between the channel and the gate electrode.

3. The semiconductor device of claim 2, further comprising:
a spacer between the channel and the gate insulation material.

4. The semiconductor device of claim 1, wherein the plurality of the first channel layers are parallel to a top surface of the substrate.

5. The semiconductor device of claim 4, wherein
the channel further includes a plurality of third channel layers spaced apart from the plurality of the first channel layers, a plurality of fourth channel layers between the plurality of the third channel layers in a direction perpendicular to the plurality of the third channel layers, and a central channel layer above the plurality of the first channel layers and the plurality of the third channel layers,
the plurality of fourth channel layers, respectively, are alternately provided at a first end of each of the plurality of third channel layers and a second end of each of the plurality of third channel layers, and
the plurality of second channel layers and the plurality of fourth channel layers are provided symmetrically with respect to a center of the central channel layer.

6. The semiconductor device of claim 1, wherein the plurality of the first channel layers are perpendicular to a top surface of the substrate.

7. The semiconductor device of claim 1, wherein the two-dimensional material has a bandgap of 0.1 eV or more.

8. The semiconductor device of claim 1, wherein the two-dimensional material comprises MoS₂, MoSe₂, MoTe₂, WS₂, or black phosphorus, or a combination thereof.

9. The semiconductor device of claim 1, wherein
in a cross-sectional cut across between the source electrode and the drain electrode, a length of one of the plurality of first channel layers is between 10 nm and 500 nm.

10. The semiconductor device of claim 1, wherein
in a cross-section cut across between the source electrode and the drain electrode, a length of one of the plurality of second channel layers is between 5 nm or more and 50 nm or less.

11. A method of manufacturing a semiconductor device, the method comprising:
stacking a first sacrificial layer and a second sacrificial layer on a substrate;
removing the second sacrificial layer;
forming a channel including a two-dimensional material on the first sacrificial layer;
removing the first sacrificial layer; and
forming a gate electrode between a source electrode and a drain electrode on the substrate, wherein
the forming the channel includes forming a plurality of first channel layers and a plurality of second channel layers,
the plurality of the first channel layers are parallel to each other and spaced apart from each other,
the plurality of the second channel layers are perpendicular to the plurality of the first channel layers and between the plurality of the first channel layers,
the plurality of second channel layers, respectively, are alternatively provided at a first end of each of the plurality of the first channel layers and a second end of each of the plurality of the first channel layers,
the forming the gate electrode includes forming the gate electrode on a first surface of each of the plurality of the first channel layers, a second surface of each of the plurality of the first channel layers, a first surface of each of the plurality of the second channel layers, and a second surface of each of the plurality of the second channel layers.

12. The method of claim 11, further comprising:
forming a gate insulation material on the channel before the forming the gate electrode, wherein
the forming the gate electrode includes forming the gate electrode on the gate insulation material so the gate insulation material is between the channel and the gate electrode.

13. The method of claim 11, wherein the plurality of the first channel layers are parallel to a top surface of the substrate.

14. The method of claim 11, wherein the plurality of the first channel layers are perpendicular to a top surface of the substrate.

15. The method of claim 11, wherein the two-dimensional material has a bandgap of 0.1 eV or more.

16. The method of claim 11, wherein the two-dimensional material comprises MoS₂, MoSe₂, MoTe₂, WS₂, or black phosphorus, or a combination thereof.
